(19) United States
(12) Patent Application Publication
(10) Pub. No.: US 2025/0063703 A1
(43) Pub. Date: Feb. 20, 2025

(54) EDGE DATA CENTER

(71) Applicant: Hebei Qinhuai Data Co., Limited., Zhangjiakou City (CN)

(72) Inventors: Binghua ZHANG, Zhangjiakou City (CN); Yongbin LIU, Zhangjiakou City (CN)

(21) Appl. No.: 18/806,277

(22) Filed: Aug. 15, 2024

(30) Foreign Application Priority Data
Aug. 15, 2023 (CN) 202311026947.5

(51) Int. Cl. H05K 7/20

(52) U.S. Cl. CPC H05K 7/20827; H05K 7/20309; H05K 7/20327

(57) ABSTRACT

Embodiments of the present disclosure provide an edge data center, belonging to the field of edge data center technology. The edge data center includes: a liquid-cooled container, a liquid-cooled server, a gravity assisted heat pipe system, and a power distribution monitoring unit. The gravity assisted heat pipe system includes an outdoor heat exchange unit, an indoor evaporative liquid cooling cold plate, and a flow distribution unit. The liquid-cooled server is arranged inside the liquid-cooled container, and a heating element of the liquid-cooled server is attached with the indoor evaporative liquid cooling cold plate. The outdoor heat exchange unit is arranged outside the liquid-cooled container, and the outdoor heat exchange unit is connected to an indoor component of the gravity assisted heat pipe system by means of a refrigerant pipe of the flow distribution unit.

### CROSS REFERENCE TO RELATED APPLICATION

This application claims priority to Chinese Patent Application No. 202311026947.5, titled “EDGE DATA CENTER” and filed to the China National Intellectual Property Administration on Aug. 15, 2023, the entire contents of which are incorporated herein by reference.

### TECHNICAL FIELD

The present disclosure relates to the field of data center technology, and more particularly, to an edge data center.

### BACKGROUND

With the development of 5G, autonomous driving, industrial Internet and telecommuting, amount of information data has surged, and demands for corresponding data analysis and processing capacity of edge data centers continuously increase, which leads to significant increase in chip computing power of the edge data centers, resulting in increasing demands for chip power consumption and heat dissipation.

The existing air-cooled data centers are phased out due to insufficient heat dissipation capability through air convection. As a technology with stronger heat dissipation capability, a liquid cooling technology has gradually become a better choice for a new generation of data center refrigeration systems.

To provide relatively low-cost and reliable liquid cooling solutions, most of existing liquid cooling data centers use cold plate liquid cooling. A cold plate liquid cooling system is typically comprised of a cooling tower, a coolant distribution unit (CDU), and a liquid cooling cabinet. Transportation of primary side cooling water and secondary side liquid cooling coolant depends on a circulating water pump. Moreover, in conventional solutions, a two-stage heat exchange system is arranged, where heat from a server is transferred to the liquid cooling coolant by means of a cold plate. Next, the liquid cooling coolant exchanges heat with the cooling water by means of a heat exchange unit (also known as a heat interchange unit) of the CDU. Finally, the heat from the cooling water is dissipated outdoors by means of the cooling tower. This heat exchange process is relatively complicated.

### SUMMARY

To solve some or all of the problems existing in the existing technology, embodiments of the present disclosure provide an edge data center, and the technical solutions are as follows.

The edge data center includes a liquid-cooled container, a liquid-cooled server, and a gravity assisted heat pipe system. The gravity assisted heat pipe system includes an outdoor heat exchange unit, an indoor evaporative liquid cooling cold plate, and a flow distribution unit.

The liquid-cooled server is arranged inside the liquid-cooled container, and a heating element of the liquid-cooled server is attached with the indoor evaporative liquid cooling cold plate.

The outdoor heat exchange unit is arranged outside the liquid-cooled container, and the outdoor heat exchange unit is connected to an indoor component of the gravity assisted heat pipe system by means of a refrigerant pipe of the flow distribution unit.

Alternatively, the edge data center also includes an air-cooled air conditioner and a power distribution monitoring unit arranged inside the liquid-cooled container, where the power distribution monitoring unit is configured to monitor and control an operating state of the air-cooled air conditioner.

Alternatively, the flow distribution unit includes a coolant distribution unit, a hose, a quick coupler, and a refrigerant pipe.

The refrigerant pipe is connected to the outdoor heat exchange unit, and the hose is connected to the evaporative liquid cooling cold plate by means of the quick coupler.

Alternatively, a thermal conductive coating is provided between the heating element and the indoor evaporative liquid cooling cold plate.

Alternatively, the air-cooled air conditioner is a fluorine pump air-cooled inter-row air conditioner.

The present disclosure adopts a containerized layout, which can meet requirements for edge high-density computing scenarios. By combining a gravity assisted heat pipe technology with cold plate liquid cooling, circulation of a refrigerant is completed by means of the gravity assisted heat pipe technology, eliminating the need for transporting the refrigerant in the liquid cooling system by means of a traditional water pump, thereby reducing pumping power consumption. Compared to a conventional two-stage heat exchange system, the present disclosure reduces primary heat exchange, which further improves the energy utilization ratio of a cooling system of the data center, and reduces structural complexity of the system. In addition, the thermal conductive coating is arranged between the heating element of the server and the cold plate, which can enhance heat exchange.

### BRIEF DESCRIPTION OF THE DRAWINGS

To describe the technical solutions in the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a container liquid cooling system according to an embodiment of the present disclosure; and

FIG. 2 is a schematic structural elevation drawing of a container liquid cooling system according to an embodiment of the present disclosure.

### DETAILED DESCRIPTION

To make the objectives, technical solutions and advantages of the present disclosure clearer, the embodiments of the present disclosure will be further described as below in details with reference to the accompanying drawings. The terms such as “upper”, “above”, “lower”, “below”, “first end”, “second end”, “one end”, “other end” as used herein, which denote spatial relative positions, describe the relationship of one unit or feature relative to another unit or feature in the accompanying drawings for the purpose of illustration. The terms of the spatial relative positions may be intended to include different orientations of a device in use or operation other than the orientations shown in the accompanying drawings. For example, a unit that is described as “below” or “under” other units or features will be “above” the other units or features when the device in the accompanying drawings is turned upside down. Thus, the exemplary term “below” may encompass both the orientations of above and below. The device may be otherwise oriented (rotated by 90 degrees or facing other directions) and the space-related descriptors used herein are interpreted accordingly.

In addition, terms “installed”, “arranged”, “provided”, “connection”, “sliding connection”, “fixed”, and “sleeved” should be understood in a broad sense. For example, the “connection” may be a fixed connection, a detachable connection or integrated connection, a mechanical connection or an electrical connection, a direct connection or indirect connection by means of an intermediary, or internal connection between two apparatuses, elements, or components. The specific significations of the above terms in the present disclosure may be understood in the light of specific conditions by persons of ordinary skill in the art.

Embodiments of the present disclosure provide an edge data center, which includes: a liquid-cooled container, a liquid-cooled server, and a gravity assisted heat pipe system. The gravity assisted heat pipe system includes an outdoor heat exchange unit, an indoor evaporative liquid cooling cold plate, and a flow distribution unit. The liquid-cooled server is arranged inside the liquid-cooled container, and a heating element of the liquid-cooled server is attached with the indoor evaporative liquid cooling cold plate. The outdoor heat exchange unit is arranged outside the liquid-cooled container, and the outdoor heat exchange unit is connected to an indoor component of the gravity assisted heat pipe system by means of a refrigerant pipe of the flow distribution unit.

In one embodiment, the edge data center also includes an air-cooled air conditioner and a power distribution monitoring unit arranged inside the liquid-cooled container, where the power distribution monitoring unit is configured to monitor and control an operating state of the air-cooled air conditioner.

In implementation, the air-cooled air conditioner may be employed to dissipate heat from non-liquid cooled components in a data center computer room.

In one embodiment, the flow distribution unit includes a coolant distribution unit, a hose, a quick coupler, and a refrigerant pipe. The refrigerant pipe is connected to the outdoor heat exchange unit, and the hose is connected to the evaporative liquid cooling cold plate by means of the quick coupler.

In implementation, the coolant distribution unit may be a manifold configured to connect water inlet and outlet pipelines of various liquid cooling cold plates. A connection method of the hose may be vertebral tube buckle type or clamp-on design, or other connection methods may also be used, but the present disclosure is not limited thereto.

In one embodiment, a thermal conductive coating is provided between the heating element and the indoor evaporative liquid cooling cold plate.

In implementation, the heating element may be a CPU (Central Processing Unit) chip or GPU (Graphics Processing Unit) chip of the server. The thermal conductive coating may use a metal-based material such as metal-based graphene composite coating, or may use a non-metallic-based material such as non-metallic-based silicone grease or organic resin. A method for spraying the thermal conductive coating may be cold spraying, supersonic plasma spraying, or thermal spraying, etc., but the present disclosure is not limited thereto.

In one embodiment, the air-cooled air conditioner is a fluorine pump air-cooled inter-row air conditioner.

In implementation, the fluorine pump air-cooled inter-row air conditioner may be arranged between server cabinets to bear air conditioning load of air-cooling portion and cool air in the data center computer room. The air-cooling portion of the server may account for 10-15% of total heat release.

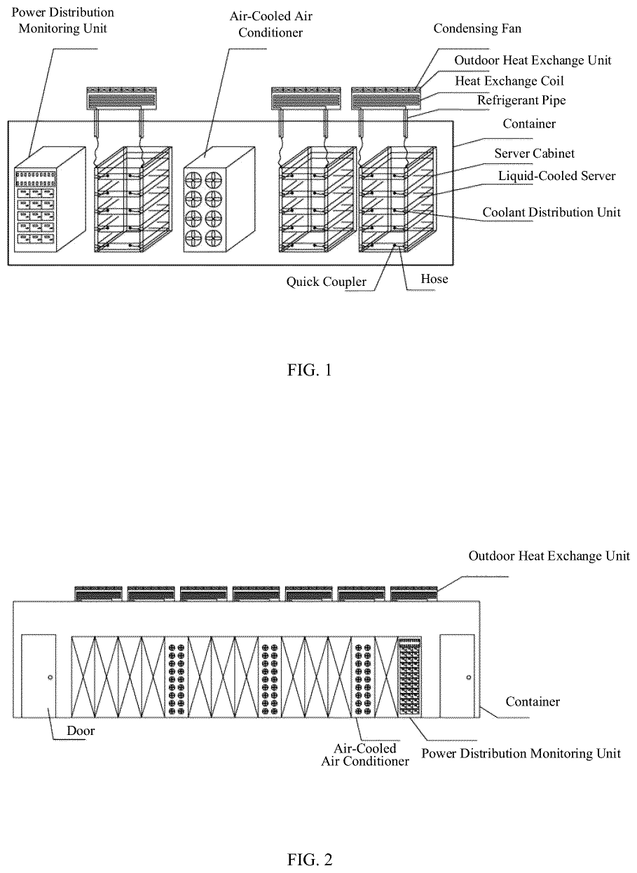

Referring to FIG. 1 and FIG. 2, the data center computer room adopts a containerized layout. One or more power distribution monitoring units, one or more server cabinets, and one or more air-cooled air conditioners may be arranged inside the liquid-cooled container. The liquid-cooled server may be arranged on the server cabinets, and each of the server cabinets is provided with a corresponding gravity assisted heat pipe system. One gravity assisted heat pipe system is used for cooling one corresponding server cabinet, and of course, one gravity assisted heat pipe system may also be used for cooling a plurality of server cabinets.

In FIG. 1, each gravity assisted heat pipe system may include: the outdoor heat exchange unit comprising a condensing fan and a heat exchange coil; the flow distribution unit comprising the coolant distribution unit, the hose, the quick coupler, and the refrigerant pipe; and the indoor evaporative liquid cooling cold plate (not shown in the figure).

In implementation, the condensing fan is configured to provide power for outdoor air, such that the outdoor air flows through the outdoor heat exchange unit and takes away heat released by the refrigerant in the heat exchange coil.

A water inlet end and a water outlet end of the heat exchange coil are connected to pipelines inside the liquid-cooled container by means of a refrigerant pipe, respectively. A water inlet end and a water outlet end of the cold plate of server are connected to the hose by means of the quick coupler, respectively. The quick coupler can ensure that the server has online plug maintenance performance.

In FIG. 2, the outdoor heat exchange unit is arranged at a top outside the container. In this way, based on technical principles of the gravity assisted heat pipe technology, the refrigerant in the pipelines can overcome pipeline resistance by taking advantage of gravity reflux and evaporative supercharging, thereby completing circulation of the refrigerant. An evaporation process of the refrigerant is completed in the cold plate of the server, which can take away the heat from the server, and then the absorbed heat is directly dissipated outside by means of the outdoor heat exchange unit, thereby reducing intermediate heat exchange processes and pumping power consumption. In the present disclosure, an upper limit of heat exchange can be increased for the liquid cooling cold plate by means of a phase change technology, such that the liquid cooling cold plate is compatible to the liquid-cooled server having requirements for higher power density.

It is worth mentioning that the refrigerant may use R134a (that is, 1,1,1,2-tetrafluoroethane, whose chemical formula is C₂H₂F₄) as an environmentally friendly refrigerant, or other refrigerants may also be used, but the present disclosure is not limited thereto.

In one embodiment, due to higher outlet temperature of the liquid cooling system, an annual Cooling Load Factor (CLF) of the liquid cooling system generally may be reduced by more than 60% in various scenarios.

In one embodiment, due to use of the gravity assisted heat pipe technology instead of transporting the refrigerant by means of a traditional water pump, an annual Power Usage Efficiency (PUE) of the liquid cooling system is reduced from 1.13 (air conditioning factor is 0.08, and power factor is 0.05) to 1.07 (the air conditioning factor is 0.02, and the power factor is 0.05). The use of the evaporative liquid cooling cold plate significantly increases a heat dissipation upper limit of power consumption of a single chip, such that heat dissipation capability of the single chip approaches the upper limit (700-900 W) under single-phase coolant technology conditions. Thus, the evaporative liquid cooling cold plate can greatly improve the heat dissipation capability of the single chip and assist in iteration of chip heat dissipation technologies.

The present disclosure adopts a containerized layout, which can meet requirements for edge high-density computing scenarios. By combining the gravity assisted heat pipe technology with cold plate liquid cooling, circulation of the refrigerant is completed by means of the gravity assisted heat pipe technology, eliminating the need for transporting the refrigerant in the liquid cooling system by means of a traditional water pump, thereby reducing pumping power consumption. Compared to a conventional two-stage heat exchange system, the present disclosure reduces primary heat exchange, which further improves the energy utilization ratio of a cooling system of the data center, and reduces structural complexity of the system. In addition, the thermal conductive coating is arranged between the heating element of the server and the cold plate, which can enhance heat exchange.

The foregoing descriptions are merely preferred embodiments of the present disclosure, and are not intended to limit the present disclosure. Any modification, equivalent replacement and improvement made within the spirit and principles of the present disclosure shall fall into the protection scope of the present disclosure.

What is claimed is:

1. An edge data center comprising: a liquid-cooled container, a liquid-cooled server, and a gravity assisted heat pipe system; wherein the gravity assisted heat pipe system comprises an outdoor heat exchange unit, an indoor evaporative liquid cooling cold plate, and a flow distribution unit;
the liquid-cooled server is arranged inside the liquid-cooled container, and a heating element of the liquid-cooled server is attached with the indoor evaporative liquid cooling cold plate; and
the outdoor heat exchange unit is arranged outside the liquid-cooled container, and the outdoor heat exchange unit is connected to an indoor component of the gravity assisted heat pipe system by means of a refrigerant pipe of the flow distribution unit.

2. The edge data center as claimed in claim 1 further comprising an air-cooled air conditioner and a power distribution monitoring unit arranged inside the liquid-cooled container, wherein the power distribution monitoring unit is configured to monitor and control an operating state of the air-cooled air conditioner.

3. The edge data center as claimed in claim 1, wherein the flow distribution unit comprises a coolant distribution unit, a hose, a quick coupler, and a refrigerant pipe; and
the refrigerant pipe is connected to the outdoor heat exchange unit, and the hose is connected to the evaporative liquid cooling cold plate by means of the quick coupler.

4. The edge data center as claimed in claim 1, wherein a thermal conductive coating is provided between the heating element and the indoor evaporative liquid cooling cold plate.

5. The edge data center as claimed in claim 2, wherein the air-cooled air conditioner is a fluorine pump air-cooled inter-row air conditioner.
